(19) United States
(12) Patent Application Publication
(10) Pub. No.: US 2026/0219464 A1
(43) Pub. Date: Jul. 30, 2026

(54) OPTICAL MODULE

(71) Applicant: InnoLight Technology (Suzhou) Ltd., Suzhou (CN)

(72) Inventors: Xigui Fang, Suzhou (CN); XIAN ZHOU, Suzhou (CN)

(21) Appl. No.: 19/578,969

(22) Filed: Mar. 26, 2026

Related U.S. Application Data
(63) Continuation of application No. PCT/CN2024/106696, filed on Jul. 22, 2024.

(30) Foreign Application Priority Data
Sep. 26, 2023 (CN) 202322613213.9

(51) Int. Cl. G02B 6/42

(52) U.S. Cl. CPC G02B 6/4278; G02B 6/428

(57) ABSTRACT

An optical module. In the optical module, a bare die is directly flip-mounted on a circuit board of the optical module, such that high-speed signals on a host side and a line side can directly enter the interior of the bare die through an electrical interface of the circuit board into the circuit board. Therefore, the link of high-speed signals can be simplified, impedance abrupt change points are reduced, the transmission stability of the high-speed signals is improved, the integrity of the signals is improved, the transmission rate is improved, and the optical module with a higher rate is implemented. Moreover, the thermal expansion coefficient of a first insulating dielectric layer of a core layer structure of the circuit board matches the thermal expansion coefficient of the bare die, which can effectively improve the reliability of the bare die flip-mounted on the circuit board.

### CROSS-REFERENCE TO RELATED PATENT APPLICATION

This application is a continuation application of International Patent Application Ser. No. PCT/CN2024/106696, filed on July 22, 2024, which the international application was published on April 3, 2025, as International Publication No. WO 2025/066474A1, and claims the priority of China Patent Application No. CN202322613213.9, filed on September 26, 2023, in People’s Republic of China. The entirety of each of the above patent applications is hereby incorporated by reference herein and made a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present application relates to the field of optical communication technology, and in particular to an optical module.

### BACKGROUND OF THE DISCLOSURE

With the rapid development of optical communications and the Internet in recent years, users' demand for networks has also increased dramatically, which has led to a rapid increase in the traffic of telecommunications backbone networks at a rate of 50% to 80% per year. In order to adapt to the trend of rapid development of the network market, the transmission rate requirements for optical modules have also been continuously improved, from 100G, 200G, 400G to 800G and even 1.6T.

The electrical chips used in current optical modules are generally semiconductor packaged chips, such as digital signal processor (DSP) chips, clock and data recovery (CDR) chips, etc., which are generally packaged on a semiconductor package substrate, which is usually prepared by semi-additive process (SAP). Specifically, the bare die is flip-chip mounted on the package substrate for packaging, and then the package substrate is electrically connected to the printed circuit board (PCB) through the ball grid array (BGA). In this mode, the high-speed signal on the host side enters the printed circuit board through the electrical interface, enters the package substrate through the strip line, microstrip line, high-frequency coupling capacitor, via hole on the printed circuit board and BGA ball, and then enters the bare die through the strip line, microstrip line, via hole and bump on the package substrate. The high-speed signal on the line side is the same.

The high-speed signal link in the above mode is complex and has many impedance abrupt change points, resulting in low transmission stability of the high-speed signal, which cannot meet the requirements of high-speed optical modules and it is difficult to further increase the rate of the optical module.

### SUMMARY OF THE DISCLOSURE

The purpose of the present application is to provide an optical module that can solve the problems existing in the prior art, such as complex links, multiple impedance abrupt change points leading to low transmission stability of high-speed signals, inability to meet the needs of high-speed optical modules, and difficulty in further improving the rate of optical modules.

In order to solve the above problems, the present application provides an optical module, and the optical module comprises: a housing and an optical assembly, a circuit board, a bare die and a surface-mount component disposed in the housing; wherein, the circuit board comprises: a core layer structure, comprising a first insulating dielectric layer and a first conductive circuit layer laminated on both sides of the first insulating dielectric layer; and at least two build-up layer structures are symmetrically laminated on both sides of the core layer structure; wherein, the two outermost layers of the at least two build-up layer structures are provided with a surface layer circuit pattern on the surface on the side of each away from the core layer structure, and the surface layer circuit pattern comprises a fine flip-chip circuit, a surface-mount circuit and an electrical interface; and the bare die is flip-chip mounted on the fine flip-chip circuit, the surface-mount component is mounted on the surface-mount circuit, and the electrical interface is configured for pluggable electrical connection with the outside.

Furthermore, a thermal expansion coefficient of the first insulating dielectric layer matches a thermal expansion coefficient of the bare die; and the thermal expansion coefficient of the first insulating dielectric layer is less than or equal to 13 ppm/°C.

Furthermore, a material of the first insulating dielectric layer is BT resin or BT-like resin.

Furthermore, each single-layer build-up layer structure comprises a second insulating dielectric layer and a second conductive circuit layer laminated on a side of the second insulating dielectric layer away from the core layer structure; wherein, the second conductive circuit layers of the two outermost layers of the build-up layer structures form the surface layer circuit patterns; and wherein, a material of the second insulating dielectric layer is BT prepreg or BT-like prepreg.

Furthermore, the second conductive circuit layers of the two outermost layers of the build-up layer structures both comprise a seed copper layer and a build-up copper layer stacked on a side of the seed copper layer away from the core layer structure; and the seed copper layer is a thin copper layer with a thickness less than or equal to 5 microns.

Furthermore, each single-layer build-up layer structure comprises a resin coated copper foil, the resin coated copper foil comprises: a copper foil and a resin coating without glass fiber, and the copper foil is located on a side of the resin coating away from the core layer structure.

Furthermore, the single-layer build-up layer structure further comprises a build-up copper layer disposed on a side of the resin coated copper foil away from the core layer structure; a thickness of the copper foil is less than or equal to 5 microns; and wherein, the copper foils and the corresponding build-up copper layers of the two outermost layers of the build-up layers form the surface layer circuit pattern.

Furthermore, a plurality of inner layer build-up layer structures are provided between the two outermost layers of the build-up layer structures and the core layer structure; a part of layers of the inner layer build-up layer structures comprise the resin coated copper foil, and are symmetrically laminated on both sides of the core layer structure; and another part of layers of the inner layer build-up layer structures comprise a second insulating dielectric layer and a second conductive circuit layer laminated on a side of the second insulating dielectric layer away from the core layer structure, and are symmetrically laminated on both sides of the core layer structure.

Furthermore, a part of layers of the build-up layer structures are configured as high-speed circuit layers, and the high-speed circuit layers and the build-up layer structures on both sides adjacent thereto comprise a resin coated copper foil.

Furthermore, the bare die comprises one or more of a digital signal processing chip, a clock and data recovery chip, a transimpedance amplifier chip, and a laser driver chip.

Furthermore, the electrical interface is a gold finger.

Furthermore, the optical module further comprises a protective layer disposed on the gold finger.

Furthermore, the protective layer is a nickel-palladium-gold plating layer.

Furthermore, the optical assembly comprises an optical transmitting subassembly and an optical receiving subassembly; and the optical transmitting subassembly and the optical receiving subassembly are electrically connected to the circuit board and electrically connected to the bare die.

Furthermore, the optical assembly comprises a photonic integrated chip; and the photonic integrated chip is flip-mounted onto the circuit board and electrically connected to the bare die.

The advantages of the present application are that: the bare die in the optical module of the present application is directly flip-chip mounted on the circuit board of the optical module, so that the high-speed signal on the host side enters the circuit board through the electrical interface of the circuit board, and directly enters the inside of the bare die through the strip line, microstrip line, high-frequency coupling capacitor, via hole and pad on the circuit board. The high-speed signal on the line side is the same, thereby simplifying the link of the high-speed signal, reducing the impedance abrupt change point, improving the transmission stability of the high-speed signal, improving the integrity of the signal, and being conducive to further improving the transmission rate of the optical module and realizing a higher-speed optical module. Moreover, the thermal expansion coefficient of the first insulating dielectric layer of the core layer structure of the circuit board matches the thermal expansion coefficient of the bare die, which can effectively improve the reliability of the bare die flip-chip mounted on the circuit board.

### BRIEF DESCRIPTION OF THE DRAWINGS

In order to more clearly illustrate the technical solutions in the embodiments of the present application, the drawings required for use in the description of the embodiments will be briefly introduced below. Obviously, the drawings described below are only some embodiments of the present application. For those skilled in the art, other drawings can be obtained based on these drawings without creative work.

FIG. 1 is an exploded schematic diagram of an optical module according to one embodiment of the present application;

FIG. 2 is a schematic diagram of the circuit board assembly structure of an optical module according to one embodiment of the present application;

FIG. 3 is a schematic structural diagram of a circuit board of Embodiment 1 of the present application;

FIG. 4 is a schematic diagram of the structure of a circuit board of Embodiment 2 of the present application;

FIG. 5 is a schematic diagram of the structure of a circuit board of Embodiment 3 of the present application; and

FIG. 6 is a schematic structural diagram of a circuit board of Embodiment 4 of the present application.

Description of reference numerals:

100. Optical module;

1. Housing; 101. Upper housing; 102. Lower housing;

2. Optical assembly;

3. Circuit board; 4. Bare die;

5. Surface-mount component; 6. Electrical connector;

7. Filling glue; 8. Protective layer;

21. Optical transmitting subassembly; 22. Optical receiving subassembly;

23. Heat sink; 24. Optical interface;

25. Optical processing component; 3001. Accommodating hole;

301. First pad; 221. Second pad;

302. Third pad; 211. Fourth pad;

31. Core layer structure; 32. Build-up layer structure;

311. First insulating dielectric layer; 312. First conductive circuit layer;

321. Second insulating dielectric layer; 322. Second conductive circuit layer;

3221. Fine flip-chip circuit; 3222. Surface-mount circuit;

3223. Electrical interface;

341. Resin coating; 342. Copper foil.

### DETAILED DESCRIPTION OF THE EXEMPLARY EMBODIMENTS

The following describes in detail the preferred embodiments of the present application in conjunction with the drawings in the specification, so as to fully introduce the technical content of the present application to those skilled in the art, to illustrate that the present application can be implemented, to make the technical content disclosed by the present application clearer, and to make it easier for those skilled in the art to understand how to implement the present application. However, the present application can be embodied in many different forms of embodiments, and the protection scope of the present application is not limited to the embodiments mentioned in the text, and the description of the embodiments below is not intended to limit the scope of the present application.

The directional terms mentioned in the present application, such as "up", "down", "front", "back", "left", "right", "inside", "outside", "side", etc., are only directions in the drawings. The directional terms used in this article are used to explain and illustrate the present application, and are not used to limit the scope of protection of the present application.

In the drawings, components with the same structure are represented by the same numerical labels, and components with similar structures or functions are represented by similar numerical labels. In addition, for the convenience of understanding and description, the size and thickness of each component shown in the drawings are arbitrarily shown, and the present application does not limit the size and thickness of each component.

### Embodiment 1

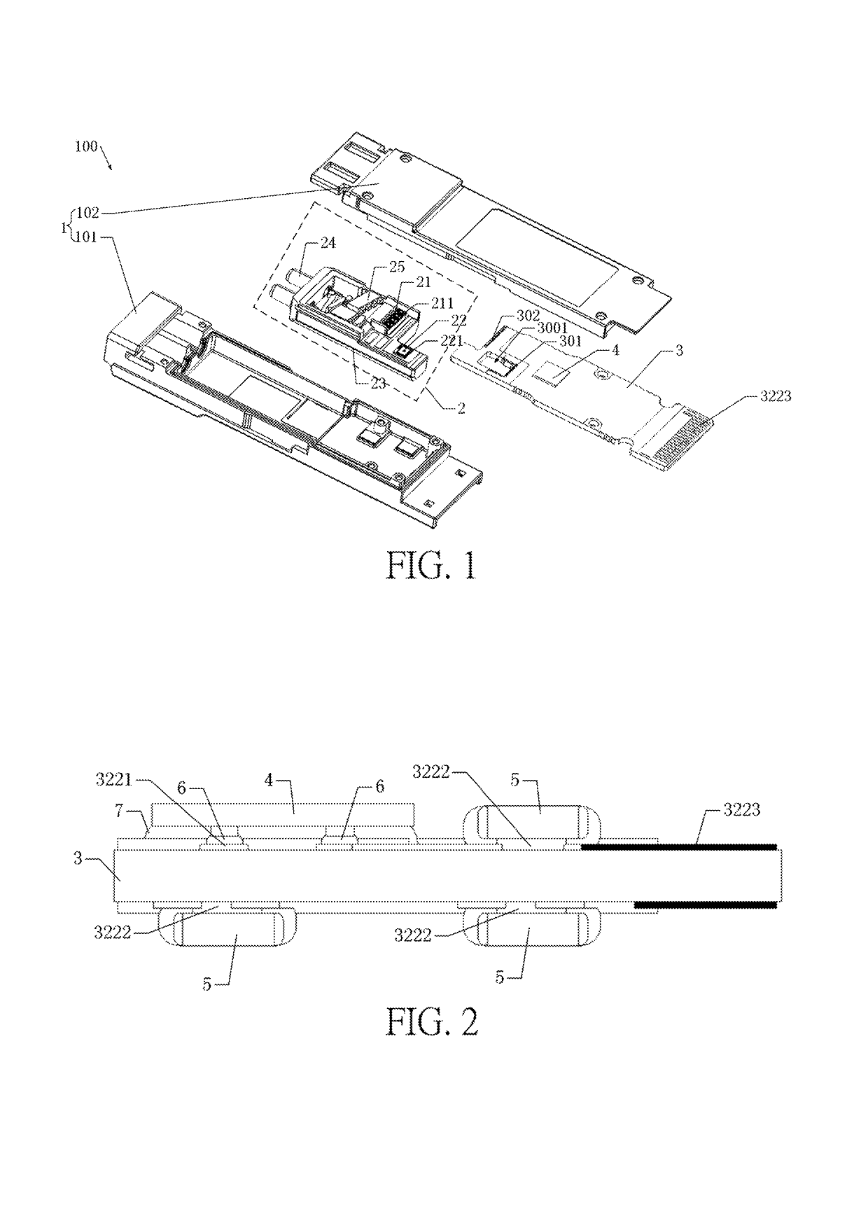

As shown in FIG. 1 and FIG. 2, the present application provides an optical module 100. The optical module 100 comprises: a housing 1, an optical assembly 2, a circuit board 3, a bare die 4, and a surface-mount component 5. The bare die 4 and the surface-mount component 5 are disposed on the circuit board 3, and the circuit board 3, the bare die 4, and the surface-mount component 5 form a Printed Circuit Board Assembly.

The housing 1 comprises an upper housing 101 and a lower housing 102 which are arranged opposite to each other.

In the present embodiment, the optical assembly 2 comprises an optical transmitting subassembly 21, an optical receiving subassembly 22, a heat sink 23, an optical interface 24 and an optical processing component 25.

The optical transmitting subassembly 21 and the optical receiving subassembly 22 are disposed on the heat sink 23 and are located on the heat sink 23 and adjacent to one end of the circuit board 3, so as to be conveniently electrically connected to the circuit board 3. The optical transmitting subassembly 21 comprises a laser chip, and the laser chip is electrically connected to the circuit board 3. The optical receiving subassembly 22 comprises a photodetector chip and an amplifier chip, the photodetector chip is electrically connected to the amplifier chip, and the amplifier chip is then electrically connected to the circuit board 3.

The heat sink 23 is disposed in the housing 1. In the present embodiment, the heat sink 23 is made of metal with good thermal conductivity, and is configured to carry the optical transmitting subassembly 21 and the optical receiving subassembly 22, and conduct the heat generated by the optical transmitting subassembly 21 and the optical receiving subassembly 22 during operation to the housing 1, so as to quickly dissipate the heat through the housing 1.

The optical interface 24 is disposed at the other end of the heat sink 23. The optical interface 24 can be a fiber receptacle or an MPO adapter, which is configured to connect to an external fiber connector to transmit optical signals to an external optical fiber, or to transmit optical signals transmitted in an external optical fiber to the optical module 100.

The optical processing component 25 is disposed on the heat sink 23, and is located between the optical interface 24 and the optical transmitting subassembly 21, and between the optical interface 24 and the optical receiving subassembly 22. The optical processing component 25 generally comprises a lens component, a wavelength division multiplexing/demultiplexing component, etc., and is configured to couple, multiplex or demultiplex the optical path.

In other embodiments, the optical assembly 2 may also comprise a photonic integrated chip. The photonic integrated chip is flip-chip mounted on the circuit board 3 and electrically connected to the bare die 4.

As shown in FIG. 1, the circuit board 3 is disposed in the housing 1, and the upper housing 101 and the lower housing 102 are covered to encapsulate the optical assembly 2 and the printed circuit board assembly (the circuit board 3 and the bare die 4 and the surface-mount components 5 thereon, etc.) in the housing 1.

The circuit board 3 has an accommodating hole 3001 at one end close to the heat sink 23. The accommodating hole 3001 is configured to accommodate the optical receiving subassembly 22. The circuit board 3 has a first pad 301 at a position close to the optical receiving subassembly 22, and the optical receiving subassembly 22 has a second pad 221, and the first pad 301 is electrically connected to the second pad 221. The electrical connection between the circuit board 3 and the optical receiving subassembly 22 is achieved through the first pad 301 and the second pad 221.

The circuit board 3 has a third pad 302 adjacent to the optical transmitting subassembly 21, the optical transmitting subassembly 21 has a fourth pad 211, and the third pad 302 is electrically connected to the fourth pad 211. The third pad 302 and the fourth pad 211 realize the electrical connection between the circuit board 3 and the optical transmitting subassembly 21.

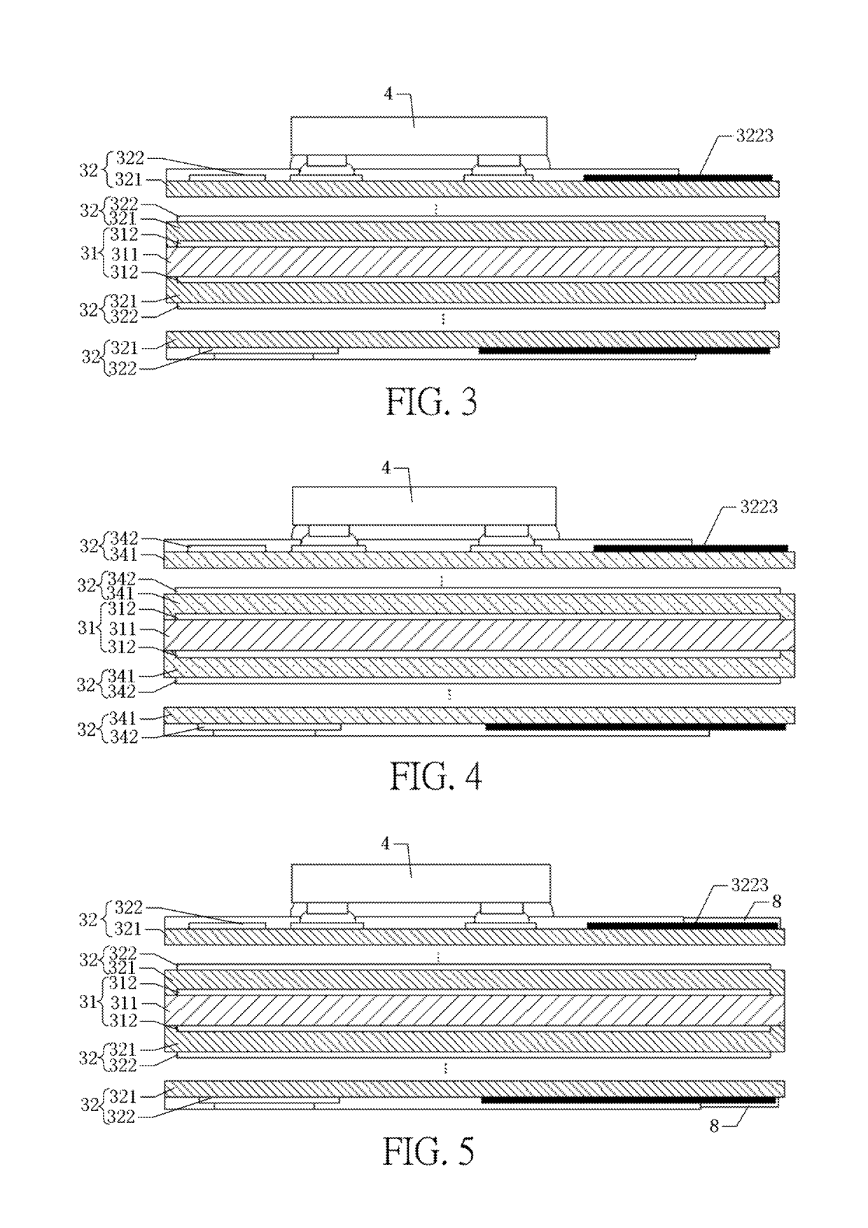

As shown in FIG. 3, the circuit board 3 in the present embodiment comprises: a core layer structure 31 and at least two build-up layer structures 32.

As shown in FIG. 3, the core layer structure 31 in the present embodiment comprises a first insulating dielectric layer 311 and a first conductive circuit layer 312 disposed on both sides of the first insulating dielectric layer 311.

The thermal expansion coefficient of the first insulating dielectric layer 311 matches the thermal expansion coefficient of the bare die 4. Specifically, the thermal expansion coefficient of the first insulating dielectric layer 311 is less than or equal to 13ppm/℃, that is, close to the thermal expansion coefficient of the bare die 4, to avoid cracking of the bare die 4 or affecting the welding reliability between the two due to deformation caused by excessive the thermal expansion coefficient. The thickness range of the first insulating dielectric layer 311 is 100um-600um. In the present embodiment, the thickness of the first insulating dielectric layer 311 is 160um. In other embodiments, the thickness of the first insulating dielectric layer 311 can also be 100 um, 120 um, 140 um, 180 um, 200 um, 250 um, 300 um, 350 um, 400 um, 450 um, 500 um, 550 um or 600um. In this way, the bare die 4 can be directly flip-chipped on the circuit board 3, while the surface-mount component 5 and the electrical interface 3223 are set on the circuit board 3.

The material of the first insulating dielectric layer 311 is BT resin or BT-like resin, so as to ensure the strength of the circuit board 3 and match the thermal expansion coefficient of the bare die 4.

The build-up layer structures 32 are symmetrically laminated on both sides of the core layer structure 31. In the present embodiment, each single-layer build-up layer structure 32 comprises a second insulating dielectric layer 321 and a second conductive circuit layer 322 laminated on a side of the second insulating dielectric layer 321 away from the core layer structure 31.

The material of the second insulating dielectric layer 321 is BT prepreg or BT-like prepreg. In the present embodiment, the material of the second insulating dielectric layer 321 is BT prepreg to ensure the strength of the circuit board 3, and at the same time can match the thermal expansion coefficient of the bare die 4, thereby supporting the modified semi-additive process (mSAP) process, and does not require the expensive semi-additive process (SAP) process, thereby reducing the production cost of the optical module 100. In addition, compared with the etching method to form a printed circuit board, it has high precision and can meet the design requirements of small pitch.

The two outermost layers of the at least two build-up layer structures 32 farthest from the core layer structure 31 on the side away from the core layer structure 31 are provided with a surface layer circuit pattern on the surface on the side of each away from the core layer structure, and the surface layer circuit pattern comprises a fine flip-chip circuit 3221, a surface-mount circuit 3222 and an electrical interface 3223. The two outermost layers of the build-up layer structures 32 are the build-up layer structures 32 laminated farthest from the core layer structure 31 on both sides. Specifically, the second conductive circuit layers 322 of the two build-up layer structures 32 farthest from the core layer structure 31 form the surface layer circuit pattern.

Specifically, the second conductive circuit layers 322 of the two build-up layer structures 32 farthest from the core layer structure 31 comprises a seed copper layer and a build-up copper layer stacked on the side of the seed copper layer away from the core layer structure 31. The seed copper layer is a thin copper layer with a thickness less than or equal to 5 microns, so that the mSAP process can be used to make the build-up copper layer on the thin copper layer and form a fine circuit. In the present embodiment, the thickness of the seed copper layer is preferably 3 microns. Therefore, the mSAP process can be used to prepare the surface layer circuit pattern on the surface of the side of the two build-up layer structures 32 farthest from the core layer structure 31 away from the core layer structure 31, and the expensive SAP process can be not required to make the fine circuit of the surface layer. Compared with the etching method to form a printed circuit board, it has high precision and can meet the design requirements of small pitch, so that the bare die 4 can be directly flip-chip mounted on the circuit board 3 to simplify the circuit between the bare die 4 and the circuit board 3, thereby improving the high-frequency performance of the optical module 100.

The build-up layer structure disposed between the core layer structure 31 and the outermost build-up layer structure may be the same as the outermost build-up layer structure, or may be a build-up layer structure of a common circuit board.

The bare die 4 is flip-chip mounted on the fine flip-chip circuit 3221. In the present embodiment, the bare die 4 comprises one or more of a digital signal processing (DSP) chip, a clock and data recovery (CDR) chip, a transimpedance amplifier chip, and a laser driver chip. The bare die 4 is directly flip-chip mounted on the fine flip-chip circuit 3221 of the circuit board 3, and is electrically connected to the circuit board 3 through the electrical connector 6. In the present embodiment, the bare die 4 has relatively dense bumps, and solder paste is employed as the electrical connector to solder the bumps of the bare die 4 and the pads of the fine flip-chip circuit 3221 on the circuit board 3. In some embodiments, when the bare die 4 has fewer bumps, the electrical connector can also utilize gold balls or anisotropic conductive glue (ACF).

The surface-mount component 5 is mounted on the surface-mount circuit 3222. The surface-mount component 5 is arranged on the circuit board 3 using the surface-mounted technology (SMT).

The electrical interface 3223 is configured for pluggable electrical connection with the outside of the optical module 100. The electrical interface 3223 is disposed at one end of the circuit board 3 away from the optical receiving subassembly 22. In the present embodiment, the electrical interface 3223 is a gold finger. Specifically, the electrical interface 3223 is a gold finger with a pattern and shape structure that conforms to the optical module MSA definition.

The optical module 100 further comprises a filling glue 7 disposed between the bare die 4 and the circuit board 3. The thermal expansion coefficient of the filling glue 7 matches the thermal expansion coefficient of the electrical connector 6, so that the filling glue 7 can better protect the electrical connector 6.

The bare die 4 in the optical module 100 of the present application is directly flip-chip mounted on the circuit board 3, so that the high-speed signal on the host side enters the circuit board 3 through the electrical interface 3223 of the circuit board 3, and directly enters the inside of the bare die 4 through the strip line, microstrip line, high-frequency coupling capacitor, via hole and pad on the circuit board 3. The high-speed signal on the line side is similar, which can simplify the link of the high-speed signal, reduce the impedance abrupt change point, improve the transmission stability of the high-speed signal, improve the integrity of the signal, and help to further improve the transmission rate of the optical module 100 and realize a higher-speed optical module 100. In addition, the thermal expansion coefficient of the first insulating dielectric layer 311 of the core layer structure 31 of the circuit board 3 matches the thermal expansion coefficient of the bare die 4, which can effectively improve the reliability of the bare die 4 flip-chip mounted on the circuit board 3.

### Embodiment 2

As shown in FIG. 4, the present embodiment comprises most of the technical features of Embodiment 1. The difference between the present embodiment and Embodiment 1 is that in the present embodiment, each single-layer build-up layer structure 32 comprises a low-loss resin coated copper foil (RCC), and the resin coated copper foil comprises: a copper foil 342 and a resin coating 341 that does not contain glass fiber, and the copper foil 342 is located on the side of the resin coating 341 away from the core layer structure 31.

The resin coating 341 does not contain glass fiber, which can eliminate the high-frequency glass fiber weave effect and improve the conductive anodic filament (CAF) resistance. The resin coated copper foil has a uniform film, which is more conducive to laser hole forming than traditional prepregs, and has stable expansion and contraction, so it can support the design of via hole with a hole diameter of 50um and a hole plate of 90um, thereby supporting a minimum pitch design of 115um, making it easier to make fine circuits on the circuit board 3.

In the present embodiment, the single-layer build-up layer structure 32 also comprises a build-up copper layer disposed on the side of the resin coated copper foil away from the core layer structure 31, and the thickness of the copper foil 342 is less than or equal to 5 microns, so that the build-up copper layer can be made on the copper foil using the mSAP process and a fine circuit can be formed. In the present embodiment, the thickness of the copper foil 342 is preferably 3 microns. In the present embodiment, the copper foils of the two build-up layer structures 32 farthest from the core layer structure 31 and the corresponding build-up copper layers form a surface layer circuit pattern. Specifically, the surface layer circuit pattern is prepared on the surface of the outermost build-up layer structure 32 away from the core layer structure 31 by using the mSAP process, which can also make fine circuits on the surface without the requirement for an expensive SAP process, thereby reducing the production cost of the optical module 100. In addition, compared with the etching method to form a printed circuit board, it has high precision and can meet the design requirements of small pitches. Therefore, the bare die 4 can be directly flip-chip mounted on the circuit board 3 to simplify the circuit between the bare die 4 and the circuit board 3, thereby improving the high-frequency performance of the optical module 100.

A plurality of inner layer build-up layer structures are disposed between the two build-up layer structures 32 farthest from the core layer structure 31 and the core layer structure 31.

In some embodiments, the inner layer build-up layer structure between the core layer structure 31 and the outermost build-up layer structure 32 can adopt the build-up layer structure 32 comprising the second insulating dielectric layer 321 and the second conductive circuit layer 322 as in Embodiment 1 as needed, or can adopt the resin coated copper foil structure as in Embodiment 2, or a combination of the two.

When the inner layer build-up layer structure adopts a combination of Embodiment 1 and Embodiment 2, that is, a part of layers of the inner layer build-up layer structures comprise a resin coated copper foil, and are symmetrically disposed on both sides of the core layer structure 31; another part of layers of the inner layer build-up layer structure comprises the second insulating dielectric layer 321 and the second conductive circuit layer 322 disposed on the side of the second insulating dielectric layer 321 away from the core layer structure 31, and is symmetrically disposed on both sides of the core layer structure 31. For example, a part of layers of the build-up layer structures 32 are configured as high-speed circuit layers, and the build-up layer structures of the high-speed circuit layer and the upper layer and the lower layer thereof (layers on both sides adjacent thereto) all use resin coated copper foil as the build-up layer structure, and other inner layers can use the build-up layer structure as in Embodiment 1 or Embodiment 2, which can eliminate the glass fiber weave effect during high-speed line transmission to avoid the glass fiber weave effect of the traditional prepreg affecting the high-frequency performance, thereby effectively improving the high-speed performance of the circuit board 3.

### Embodiment 3

As shown in FIG. 5, the present embodiment comprises most of the technical features of Embodiment 1. Since the surface layer circuit pattern is made by the mSAP process, it comprises a gold finger located on the surface, and the wear resistance of the gold finger is relatively weak. The difference between the present embodiment and Embodiment 1 is that in the present embodiment, in order to improve the plugging and unplugging wear resistance and anti-oxidation and corrosion resistance of the gold finger, a protective layer 8 is provided on the gold finger in the present embodiment. Specifically, the protective layer 8 can be a nickel-palladium-gold plating layer, that is, after the surface layer circuit pattern is made by the mSAP process, a nickel-palladium-gold plating layer is plated on the gold finger as the protective layer 8 of the gold finger. The nickel-palladium-gold plating layer has good wear resistance and anti-oxidation and corrosion resistance.

### Embodiment 4

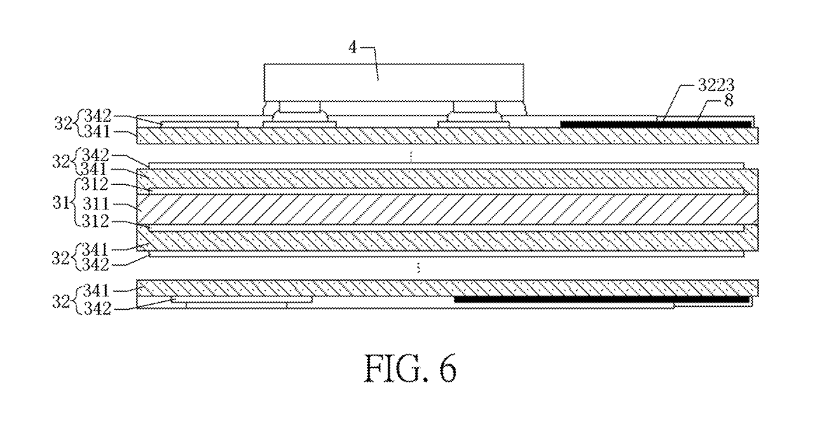

As shown in FIG. 6, the present embodiment comprises most of the technical features of Embodiment 2. The difference between the present embodiment and Embodiment 2 is that in the present embodiment, in order to improve the plugging and unplugging wear resistance and the anti-oxidation and corrosion resistance of the gold finger, a protective layer 8 is provided on the gold finger. Specifically, the protective layer 8 can be a nickel-palladium-gold plating layer, and the reference can be made to Embodiment 3.

Furthermore, the above is a detailed introduction to an optical module provided by the present application. Specific examples are used in this article to illustrate the principles and implementation methods of the present application. The description of the above embodiments is only used to help understand the core idea of the present application. At the same time, for technical personnel in this field, according to the idea of the present application, there will be changes in the specific implementation methods and application scope. In summary, the content of this specification should not be understood as a limitation on the present application.

1. An optical module, comprising: a housing,
and an optical assembly, a circuit board, a bare die and a surface-mount component disposed in the housing;
wherein, the circuit board comprises:
a core layer structure, comprising a first insulating dielectric layer and a first conductive circuit layer laminated on both sides of the first insulating dielectric layer; and
at least two build-up layer structures are symmetrically laminated on both sides of the core layer structure;
wherein, the two outermost layers of the at least two build-up layer structures are provided with a surface layer circuit pattern on the surface on the side of each away from the core layer structure, and the surface layer circuit pattern comprises a fine flip-chip circuit, a surface-mount circuit and an electrical interface; and
the bare die is flip-chip mounted on the fine flip-chip circuit, the surface-mount component is mounted on the surface-mount circuit, and the electrical interface is configured for pluggable electrical connection with the outside.

2. The optical module according to claim 1, wherein, a thermal expansion coefficient of the first insulating dielectric layer matches a thermal expansion coefficient of the bare die; and the thermal expansion coefficient of the first insulating dielectric layer is less than or equal to 13 ppm/°C.

3. The optical module according to claim 1, wherein a material of the first insulating dielectric layer is BT resin or BT-like resin.

4. The optical module according to claim 1, wherein each single-layer build-up layer structure comprises a second insulating dielectric layer and a second conductive circuit layer laminated on a side of the second insulating dielectric layer away from the core layer structure;
wherein, the second conductive circuit layers of the two outermost layers of the build-up layer structures form the surface layer circuit patterns; and
wherein, a material of the second insulating dielectric layer is BT prepreg or BT-like prepreg.

5. The optical module according to claim 4, wherein the second conductive circuit layers of the two outermost layers of the build-up layer structures both comprise a seed copper layer and a build-up copper layer stacked on a side of the seed copper layer away from the core layer structure; and
the seed copper layer is a thin copper layer with a thickness less than or equal to 5 microns.

6. The optical module according to claim 1 is wherein each single-layer build-up layer structure comprises a resin coated copper foil, the resin coated copper foil comprises: a copper foil and a resin coating without glass fiber, and the copper foil is located on a side of the resin coating away from the core layer structure.

7. The optical module according to claim 6, wherein the single-layer build-up layer structure further comprises a build-up copper layer disposed on a side of the resin coated copper foil away from the core layer structure;
a thickness of the copper foil is less than or equal to 5 microns; and
wherein, the copper foils and the corresponding build-up copper layers of the two outermost layers of the build-up layers form the surface layer circuit pattern.

8. The optical module according to claim 4, wherein a plurality of inner layer build-up layer structures are provided between the two outermost layers of the build-up layer structures and the core layer structure;
a part of layers of the inner layer build-up layer structures comprise the resin coated copper foil, and are symmetrically laminated on both sides of the core layer structure; and
another part of layers of the inner layer build-up layer structures comprise a second insulating dielectric layer and a second conductive circuit layer laminated on a side of the second insulating dielectric layer away from the core layer structure, and are symmetrically laminated on both sides of the core layer structure.

9. The optical module according to claim 7, wherein a plurality of inner layer build-up layer structures are provided between the two outermost layers of the build-up layer structures and the core layer structure;
a part of layers of the inner layer build-up layer structures comprise the resin coated copper foil, and are symmetrically laminated on both sides of the core layer structure; and
another part of layers of the inner layer build-up layer structures comprise a second insulating dielectric layer and a second conductive circuit layer laminated on a side of the second insulating dielectric layer away from the core layer structure, and are symmetrically laminated on both sides of the core layer structure.

10. The optical module according to claim 1 is wherein a part of layers of the build-up layer structures are configured as high-speed circuit layers, and the high-speed circuit layers and the build-up layer structures on both sides adjacent thereto comprise a resin coated copper foil.

11. The optical module according to claim 1, wherein the bare die comprises one or more of a digital signal processing chip, a clock and data recovery chip, a transimpedance amplifier chip, and a laser driver chip.

12. The optical module according to claim 1, wherein the electrical interface is a gold finger.

13. The optical module according to claim 12, further comprising a protective layer disposed on the gold finger.

14. The optical module according to claim 13, wherein the protective layer is a nickel-palladium-gold plating layer.

15. The optical module according to claim 1, wherein the optical assembly comprises an optical transmitting subassembly and an optical receiving subassembly; and
the optical transmitting subassembly and the optical receiving subassembly are electrically connected to the circuit board and electrically connected to the bare die.

16. The optical module according to claim 1, wherein the optical assembly comprises a photonic integrated chip; and
the photonic integrated chip is flip-chip mounted onto the circuit board and electrically connected to the bare die.
